(19) United States
(12) Patent Application Publication
(10) Pub. No.: US 2026/0282266 A1
(43) Pub. Date: Sep. 17, 2026

(54) DATA CENTER MICRO-MODULE DEVICE

(71) Applicant: SHENZHEN ENVICOOL TECHNOLOGY CO., LTD., Shenzhen City (CN)

(72) Inventors: WENCHAO YIN, Shenzhen City (CN); JIANGCHENG RAN, Shenzhen City (CN)

(73) Assignee: SHENZHEN ENVICOOL TECHNOLOGY CO., LTD., Shenzhen City (CN)

(21) Appl. No.: 19/668,729

(22) Filed: May 5, 2026

Related U.S. Application Data
(63) Continuation of application No. PCT/CN2025/083291, filed on Mar. 19, 2025.

(30) Foreign Application Priority Data
Apr. 11, 2024 (CN) 202420774780.4

(51) Int. Cl. H05K 7/14

(52) U.S. Cl. CPC H05K 7/1494; H05K 7/1491

(57) ABSTRACT

A data center micro-module device includes a rack and a door assembly attached on the rack. The rack includes a closed channel arranged inside thereof. The door assembly includes a door case mounted on the rack and an access door which is movable relative to the door case between an open state in which the closed channel is open and a close state in which the closed channel is closed. An installation bracket and a wire-tying board are arranged inside the door case. A control and monitoring equipment is mounted on the installation bracket and cables of control and monitoring equipment are secured to the wire-tying board. Thus, the environmental control boxes and monitoring materials do not need to occupy the space inside the rack of the data center micro-module device, and the issue of unsightly wiring is solved.

### CROSS REFERENCE TO RELATED APPLICATIONS

The present application is a continuation application of the international patent application No. PCT/CN2025/083291 filed on Mar. 19, 2025, which claims priority of the Chinese patent application No. 202420774780.4 filed on Apr. 11, 2024. Contents of the related applications are incorporated herein by its entireties.

### FIELD

The present application relates to the technical field of data centers, and in particular to a data center micro-module device.

### BACKGROUND

A micro-module data center generally refers to a data center consisted of modular systems such as a power supply and distribution system, a cooling system, a management and control system, a structural system, a comprehensive cabling system, and a fire protection interlocking system. A micro-module data center is an integrated, standardized, optimized infrastructure environment and highly available computing environment with strong applicability. It not only possesses the basic functions of a traditional data center but also possesses the advantages of high efficiency, energy savings, and rapid deployment.

Currently, it is known that the design of a data center micro-module device needs to consider the installation of micro-module dynamic environment control boxes and monitoring materials, such as skylight control boxes (magnetic lock for controlling the skylight), access controller boxes, ambient light control boxes, automatic reset skylight control boxes, monitoring hosts, switches, NVRs, etc. These control boxes and monitoring materials are usually installed in the management and control cabinets within the enclosed channels of the data center micro-module device, thereby occupying the rack space of the data center micro-module device. Alternatively, to avoid occupying the rack space of the central micro-module device, these control boxes and monitoring materials may be installed on top of the enclosed channels or above the fixed skylight. However, this solution leads to the issues such as inconvenient subsequent maintenance and unsightly wiring.

### SUMMARY

It is desired to provide an improved data center micro-module device to solve at least one issue mentioned above.

In one aspect, the present application provides a data center micro-module device which comprises a rack comprising a closed channel arranged inside thereof, a door assembly attached on the rack. The door assembly comprises a door case mounted on the rack and an access door which is movable relative to the door case between an open state in which the closed channel is open and a close state in which the closed channel is closed. An installation bracket and a wire-tying board are arranged inside the door case.

In an optional embodiment, a control and monitoring equipment is mounted on the installation bracket; cables of control and monitoring equipment are typed on the wire-tying board; and the door case comprises a receiving space for accommodating the installation bracket, the wire-tying board, and the control and monitoring equipment.

In an optional embodiment, the control and monitoring equipment at least comprises a skylight control box, a skylight automatic reset control box, an access controller box, an ambient light controller, a monitoring host, a video recorder, and a switch.

In an optional embodiment, a post is arranged in the door case; the installation bracket is installed on an inner wall of the door case and the post; the wire-tying board is set on the post; and the installation bracket comprises multiple layers arranged along a height direction of the post to provide more sub-spaces for installation of the control and monitoring equipment.

In an optional embodiment, the post has a height which is equal to that of the door case.

In an optional embodiment, the data center micro-module device further comprises cabinets arranged in the rack, and the cabinets are arranged at opposite sides of the closed channel.

In an optional embodiment, the data center micro-module device further comprises a roof arranged at a top of the closed channel to cover the closed channel, and the roof, the cabinets, and the door assembly cooperate to form and delimit the closed channel.

In an optional embodiment, the data center micro-module device further comprises a bridge for wiring, and the bridge crosses over the closed channel and opposite ends of the bridge are attached on top of the cabinets disposed on opposite sides of the closed channel.

In an optional embodiment, a display device is located above the access door, and ambient lights are arranged around the display device.

In an optional embodiment, a surrounding plate is provided on a periphery of a top of the rack, a light strip is provided on the surrounding plate, and the light strip is electrically connected to the ambient lights.

In an optional embodiment, the light strip mounted on the surrounding plate is electrically connected to the ambient lights around the display device to form a continuous light strip loop.

In an optional embodiment, a groove is defined at an outer surface of the surrounding plate and the light strip is received in the groove.

In an optional embodiment, the door case comprises an openable and closable door arranged at a side thereof opposite to the cabinets.

In an optional embodiment, the openable and closable door comprises a recess formed at a surface opposite to the cabinets, and a logo display device is mounted in the recess; the logo display device comprises a frame, a logo silk-screen decorative plate, and a light bar; the bracket is mounted in the recess; the logo silk-screen decorative plate and the light bar are mounted on the frame; and the logo silk-screen decorative plate is flush with the surface of the door case.

In an optional embodiment, the logo silk-screen decorative plate has an area greater than that of the frame; the logo silk-screen decorative plate covers the frame such that a periphery of the logo silk-screen decorative plate extends beyond the frame; andthe light bar is mounted on the periphery of the logo silk-screen decorative plate.

In an optional embodiment, a transparent blocking plate is mounted on the bracket and located above the light bar, and the logo silk-screen decorative plate is located above the bracket and the transparent blocking plate.

In an optional embodiment, the transparent blocking plate is an acrylic plate.

In an optional embodiment, the frame is a square hollow frame and the light bar is located below the logo silk-screen decorative plate.

In an optional embodiment, the data center micro-module device further comprises a display screen, an access controller, and an emergency stop button which are installed on the openable and closable door of the door case; and the access controller and the emergency stop button are adjacent to the display screen.

In an optional embodiment, the access door is a slidable glass door which is capable of sliding into or out of the door case in a translational manner.

### BRIEF DESCRIPTION OF THE DRAWINGS

Implementations of the present disclosure will now be described, by way of embodiment, with reference to the attached figures. It should be understood, the drawings are shown for illustrative purpose only, for ordinary person skilled in the art, other drawings obtained from these drawings without paying creative labor by an ordinary person skilled in the art should be within scope of the present disclosure.

FIG. 1 is a schematic perspective view of a data center micro-module device according to an embodiment of the present application;

FIG. 2 is a side view of the data center micro-module device shown in FIG. 1;

FIG. 3 is similar to FIG. 2 but with an openable and closable door of a door case being removed;

FIG. 3A illustrates a closed channel formed inside a rack of a data center micro-module device shown in FIG. 1;

FIG. 3B is an enlarged view of a part 3B of the data center micro-module device shown in FIG. 3;

FIG. 4 is a top plan view of the data center micro-module device shown in FIG. 1;

FIG. 5 illustrates a logo display device according to an embodiment of the present application; and

FIG. 6 illustrates a logo display device according to an alternative embodiment of the present application.

### REFERENCE SIGNS

1: cabinet, 2:door assembly, 21: door case; 210: control and monitoring equipment; 2102: cable; 211: installation bracket; 212: wire-tying board; 213: openable and closable door; 214: locking device; 215: post; 22: access door; 23: display device; 3: surrounding plate; 31: light strip; 4: logo display device; 41: logo silk-screen decorative plate; 42: frame; 43: light bar; 44: transparent blocking plate; 5: display screen; 6: access controller; 7: emergency stop button; 8: skylight; 9: bridge.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The terms indicating orientation such as "upper", "lower", "left", "right", "center", "vertical", "horizontal", "inner", and "outer" are used merely to indicate relative directions or positional relationships, rather than implying that the device or element must have a specific orientation, or be constructed and operated in a specific orientation. If the absolute position of the described object changes, its relative positional relationship may also change accordingly. Therefore, such terms shall not be construed as limitations of the present application. The term “comprising” when utilized, means “including, but not necessarily limited to”; it specifically indicates open-ended inclusion in the so-described combination, group, series, and the like. the present disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”. In addition, the terms "first" and "second" are used for descriptive purposes only and cannot be understood as indicating or implying relative importance or implying the number of indicated technical features. Thus, the features defined as "first" and "second" may explicitly or implicitly include one or more of the said features. In the description of embodiments of the application, "a plurality of" means two or more, unless otherwise specifically defined.

In the description of the application, it should be noted that unless otherwise expressly stated and defined, terms “mount”, “link” and “connection” should be understood in a broad sense. For example, “connection” may refer to fixed connection, detachable connection or integrated connection; direct connection, indirect connection by means of an intermediate medium, or internal communication of two elements. Those skilled in the art may understand the specific meanings of these terms in the application under specific circumstances.

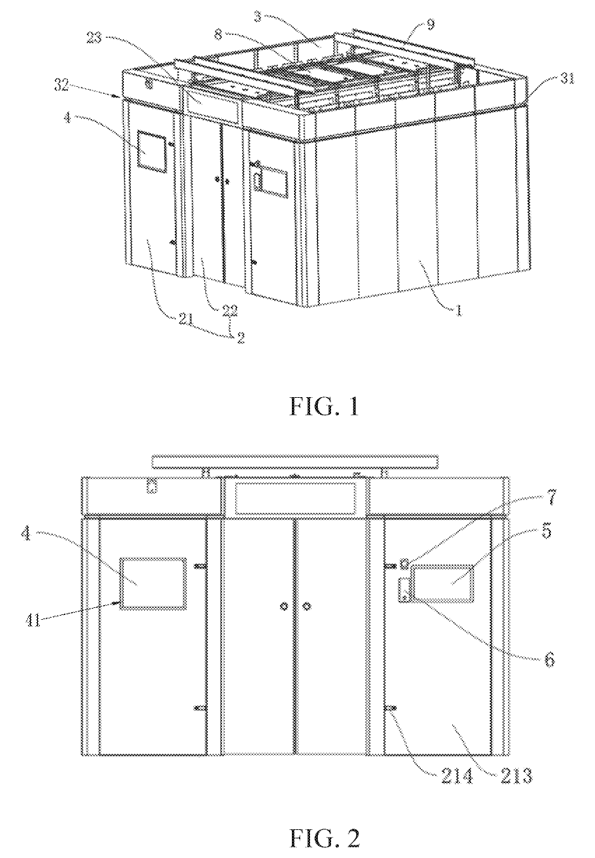

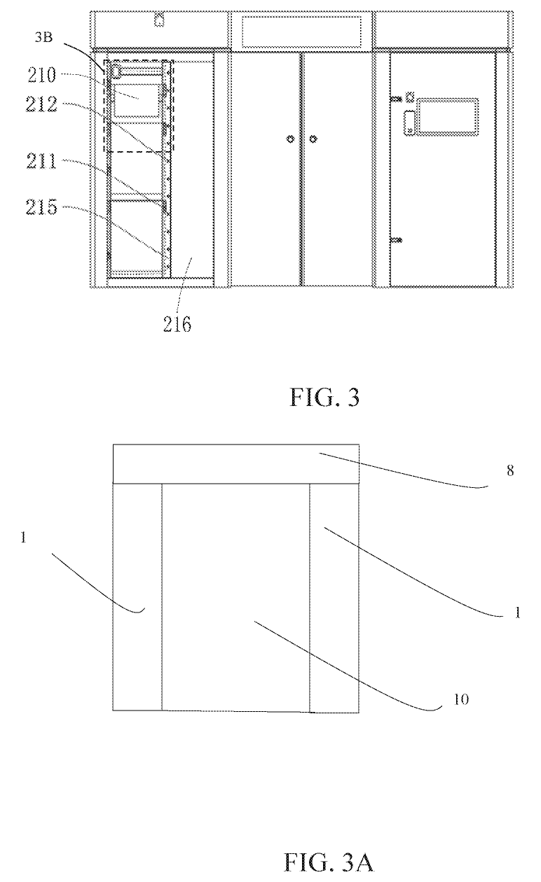

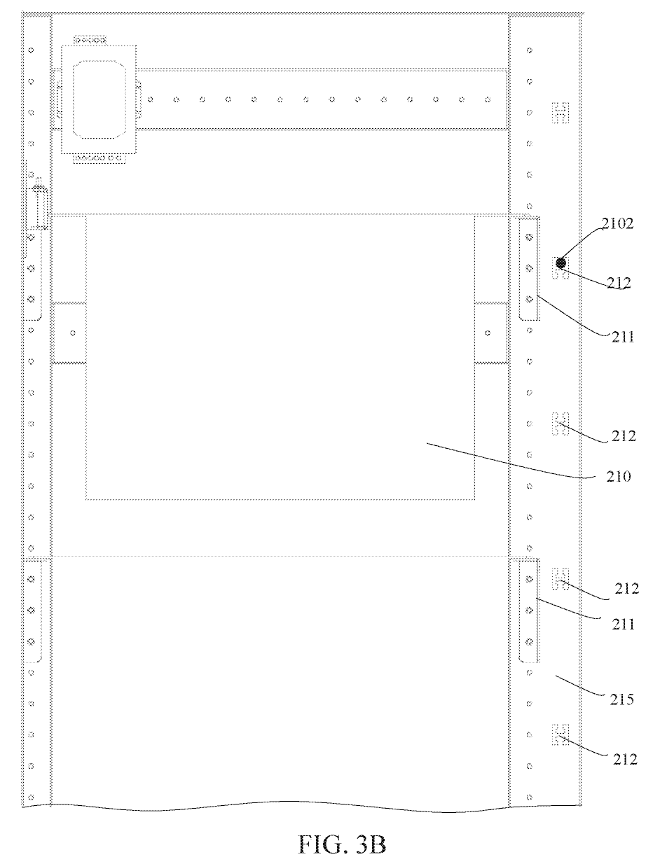

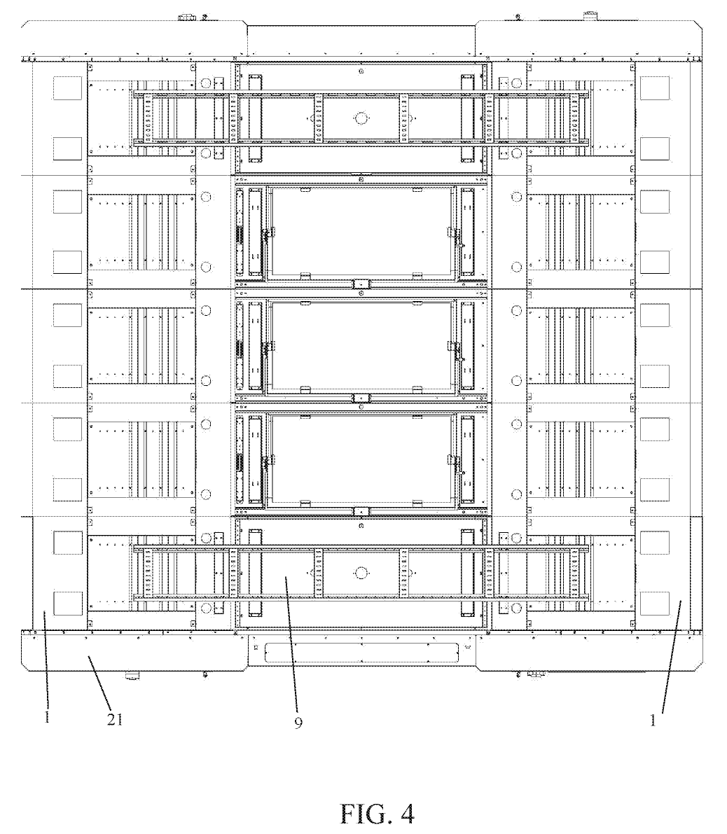

As shown in FIGS. 1-4, a data center micro-module device in accordance with an embodiment of the present application comprises a rack and a door assembly 2 arranged on the rack. The rack comprises a closed channel 10 arranged inside thereof. The door assembly 2 comprises a door case 21 arranged on the rack and an access door 22 which is movable relative to the door case 21. The access door 22 is movable relative to the door case 21 between an open state in which the closed channel is open and a close state in which the closed channel is closed. An installation bracket 211 and a wire-tying board 212 are arranged inside the door case 21.

By setting the installation bracket 211 and the wire-tying board 212 inside the door case 21 of the door assembly 2, the dynamic environmental control boxes and monitoring materials can be placed on the installation bracket 211 inside the door case 21 and cables 2102 can be secured to the wire-tying board 212 inside the door case 21. Thus, the environmental control boxes and monitoring materials do not need to occupy the space inside the rack of the data center micro-module device, and the issue of unsightly wiring is solved. Moreover, the dynamic environmental control boxes and monitoring materials being arranged inside the door case 21 makes it easier to maintain the dynamic environmental control boxes and monitoring materials. Here, the dynamic environmental control boxes and monitoring materials refer to the control and monitoring equipment 210 which is installed on the installation bracket and the cables 2102 of the control and monitoring equipment 210 are secured to the wire-tying board 212. The door case 21 comprises a receiving space 216 for accommodating the equipment 210. The equipment 210 at least comprises a skylight control box, a skylight automatic reset control box, an access controller box, an ambient light controller, a monitoring host, a video recorder, and a switch.

Specifically, the closed channel 10 can be formed by plates or by a pair of cabinets 1 arranged opposite to each other and other components. In this embodiment, the rack of the data center micro-module device comprises a group of cabinets 1 which are arranged on opposite sides of the closed channel 10. The cabinets 1 form opposite sidewalls of the closed channel 10.

Specifically, in this embodiment, the data center micro-module device further comprises a roof 8 arranged on the top of the closed channel 10 to cover the closed channel 10. The roof 8, the cabinets 1, the door assembly 2 and the ground cooperate to form and delimit the closed channel 10, ensuring the safety of the cabinets 1 inside the data center micro-module device and facilitating the control of the environmental temperature of spaces formed in the cabinets 1.

In this embodiment, the installation bracket 211 is specifically a 19-inch bracket, facilitating the installation and wiring of the standard 19-inch monitoring materials and control boxes of the data center micro-module without occupying the space inside the cabinets 1. To make the installation bracket 211 stable and facilitate the setting of the wire-tying board 212, a post 215 is arranged in the door case 21. The installation bracket 211 is installed on the inner walls of the door case 21 and the post 215, and the wire-tying board 212 is set on the post 215. The height of the post 215 can be equal to that of the door case 21, and the installation bracket 211 can comprises multiple layers arranged along the height direction of the post 215 to provide more sub-spaces for the installation of the control and monitoring equipment.

Optionally, the data center micro-module device further comprises a bridge 9 for wiring. The bridge 9 crosses over the closed channel 10 and opposite ends of the bridge 9 are attached on the top of the cabinets 1 located on opposite sides of the closed channel 10. Wiring through the bridge 9 facilitates the wiring of the monitoring and control lines of the cabinets on both sides, making the lines more concentrated. The lines are not directly visible from the top of the cabinets 1, making the overall appearance of the data center micro-module device neater.

In some embodiments, the door case 21 comprises a receiving space 216 for accommodating the installation bracket 211 and the wire-tying board 212. The door case 21 further comprises an openable and closable door 213 arranged at a side thereof away from the cabinets 1. A locking device 214 is arranged on the door 213 and configured to lock the door 213. The locking device 214 can be a mechanical lock. The openable and closable door 213 is rotatably installed on the door case 21 through hinges. The openable and closable door 213 of the door case 21 of the door assembly 2 is locked by the mechanical lock to ensure the safety of the monitoring materials and control box installed inside the door case 21. When maintenance of the monitoring materials and control box inside the door case 21 is required, the mechanical lock can be unlocked.

In some embodiments, a display device 23 is located above the access door 22, and the display device 23 is surrounded by ambient lights. The display device 23 above the access door 22 is a display screen which displays preset content according to actual needs. The ambient lights around the display device 23 can be warning lights configured to issue warning light signals when the data center micro-module device malfunctions.

In some embodiments, the periphery of the top of the cabinets 1 is provided with a surrounding plate 3, and a light strip 31 is mounted on the surrounding plate 3. The light strip 31 is electrically connected to the ambient lights. In a specific example, the light strip 31 mounted on the surrounding plate 3 at the top of the cabinets 1 is electrically connected to the light strip inside the ambient lights around the display device 23 located above the access door 22 to form a continuous light strip loop, allowing operation and maintenance personnel to observe the alarm lighting around the entire data center micro-module device the without any blind spots, ensuring that abnormal information of the data center micro-module device can be received promptly.

As shown in FIGS. 1 and 2, a groove 32 is defined in the outer side of the surrounding plate 3 to receive the light strip 31 therein so as to protect the light strip 31.

Referring to FIGS. 1-2 and 5, in some embodiments, the data center micro-module device further comprises a logo display device 4. The openable and closeable door of the door case 21 defines a recess for mounting the logo display device 4 therein. The logo display device 4 comprises a frame 42, a logo silk-screen decorative plate 41, and a light bar 43. The frame 42 is installed in the recess, and the logo silk-screen decorative plate 41 and the light bar 43 are both installed on the frame 42. The logo silk-screen decorative plate 41 is flush with the surface of the door case 21. The frame 42 can be a square hollow frame, and the logo silk-screen decorative plate 41 is silk-screened with the corresponding logo/trademark according to actual needs. The logo silk-screen decorative plate 41 is suspended by the frame 42, and the light bar 43 is arranged below the logo silk-screen decorative plate 41. The light bar 43 illuminates the suspended logo silk-screen decorative plate 41, creating a suspended effect and highlighting the visual effect of the logo.

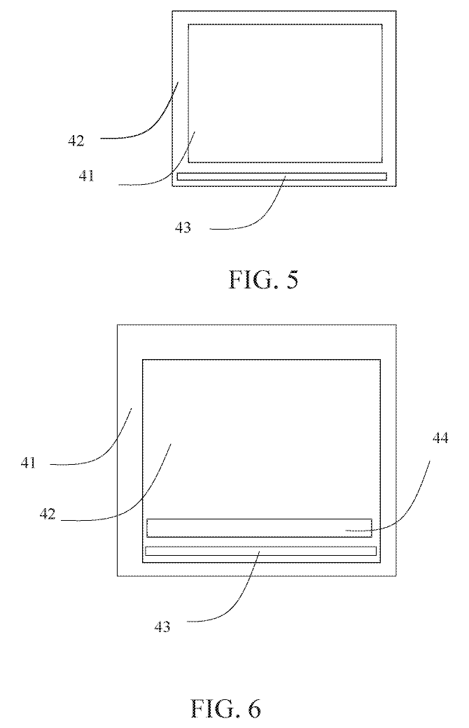

Referring to FIG. 6, in some embodiments, the area of the logo silk-screen decorative plate 41 is larger than that of the frame 42, and the light bar 43 is arranged around the frame 42. A transparent blocking plate 44 is mounted on the frame 42 above the light bar 43. The logo silk-screen decorative plate 41 completely covers the frame 42, making the edge of the logo silk-screen decorative plate 41 suspended. The light bar 43 can be mounted on the inner side or outer side of the frame 42. In this embodiment, the transparent blocking plate 44 is an acrylic plate. By setting the acrylic plate above the light bar 43, the light emitted by the light bar 43 can be weakened, making it softer and avoiding dazzling light.

In some embodiments, as shown in FIG. 2, the data center micro-module device further comprises a display screen 5, an access controller 6, and an emergency stop button 7 which are all installed on the door case 21. The access controller 6 and the emergency stop button 7 are adjacent to the display screen 5. On the right side of the access door 22, the display screen 5, the access controller 6, and the emergency stop button 7 are integrated on the door case 21, making the appearance of the data center micro-module device more unified and the wiring more centralized and convenient.

In some embodiments, the access door 22 is a slidable glass door which is capable of sliding into or out of the door case 21 in a translational manner. When the passage is opened, the access door 22 slides into the door case 21 such that the access door 22 is concealed. Compared with other embodiments in which the access door 22 is opened in a pivoting manner, the data center micro-module unit of the present embodiment occupies a smaller space.

The data center micro-module device provided by the above embodiments of this application has at least the following advantage:
1. The micro-module dynamic environment control box and monitoring materials are installed in the internal space of the door case 21, without occupying the rack space of the cabinets 1, allowing the cabinets 1 to accommodate more servers.
2. The light strip 31 on the surrounding plate 3 of the cabinets 1 is connected to the internal light strip of the atmosphere light above the top of the access door 22 to form a continuous light strip loop. This ensures good continuity and allows operation and maintenance personnel to observe the alarm lighting without any blind spots.
3. The combination of light bar and logo plate creates a suspended effect, highlighting the visual effect of the logo.
4. The display screen 5, the access controller 6, and the emergency stop button 7 are integrated together, resulting in an integral appearance and facilitating centralized wiring.

The above description is merely some embodiments. It should be noted that for one with ordinary skills in the art, improvements can be made without departing from the concept of the present disclosure, but these improvements shall fall into the protection scope of the present disclosure.

What is claimed is:

1. A data center micro-module device, comprising:
a rack comprising a closed channel arranged inside thereof; and
a door assembly attached on the rack;
wherein the door assembly comprises a door case mounted on the rack and an access door which is movable relative to the door case between an open state in which the closed channel is open and a close state in which the closed channel is closed; and
an installation bracket and a wire-tying board are arranged inside the door case.

2. The data center micro-module device according to claim 1, wherein a control and monitoring equipment is mounted on the installation bracket;
cables of control and monitoring equipment are secured to the wire-tying board; and
the door case comprises a receiving space for accommodating the installation bracket, the wire-tying board, and the control and monitoring equipment.

3. The data center micro-module device according to claim 2, wherein the control and monitoring equipment at least comprises a skylight control box, a skylight automatic reset control box, an access controller box, an ambient light controller, a monitoring host, a video recorder, and a switch.

4. The data center micro-module device according to claim 2, wherein a post is arranged in the door case;
the installation bracket is installed on an inner wall of the door case and the post;
the wire-tying board is set on the post; and
the installation bracket comprises multiple layers arranged along a height direction of the post to provide more sub-spaces for installation of the control and monitoring equipment.

5. The data center micro-module device according to claim 4, wherein the post has a height which is equal to that of the door case.

6. The data center micro-module device according to claim 1, further comprising cabinets arranged in the rack, wherein the cabinets are arranged at opposite sides of the closed channel.

7. The data center micro-module device according to claim 6, further comprising a roof arranged at a top of the closed channel to cover the closed channel, wherein the roof, the cabinets, and the door assembly cooperate to form and delimit the closed channel.

8. The data center micro-module device according to claim 6, further comprising a bridge for wiring, wherein the bridge crosses over the closed channel and opposite ends of the bridge are attached on top of the cabinets disposed on opposite sides of the closed channel.

9. The data center micro-module device according to claim 1, wherein a display device is located above the access door, and ambient lights are arranged around the display device.

10. The data center micro-module device according to claim 9, wherein a surrounding plate is provided on a periphery of a top of the rack, a light strip is provided on the surrounding plate, and the light strip is electrically connected to the ambient lights.

11. The data center micro-module device according to claim 10, wherein the light strip mounted on the surrounding plate is electrically connected to the ambient lights around the display device to form a continuous light strip loop.

12. The data center micro-module device according to claim 10, wherein a groove is defined at an outer surface of the surrounding plate and the light strip is received in the groove.

13. The data center micro-module device according to claim 1, wherein the door case comprises an openable and closable door arranged at a side thereof opposite to the cabinets.

14. The data center micro-module device according to claim 13, wherein the openable and closable door comprises a recess formed at a surface opposite to the cabinets, and a logo display device is mounted in the recess; and
the logo display device comprises a frame, a logo silk-screen decorative plate, and a light bar;
the bracket is mounted in the recess;
the logo silk-screen decorative plate and the light bar are mounted on the frame; and
the logo silk-screen decorative plate is flush with the surface of the door case.

15. The data center micro-module device according to claim 14, wherein the logo silk-screen decorative plate has an area greater than that of the frame;
the logo silk-screen decorative plate covers the frame such that a periphery of the logo silk-screen decorative plate extends beyond the frame; and
the light bar is mounted on the periphery of the logo silk-screen decorative plate.

16. The data center micro-module device according to claim 15, wherein a transparent blocking plate is mounted on the frame and located above the light bar, and the logo silk-screen decorative plate is located above the bracket and the transparent blocking plate.

17. The data center micro-module device according to claim 16, wherein the transparent blocking plate is an acrylic plate.

18. The data center micro-module device according to claim 14, wherein the frame is a square hollow frame and the light bar is located below the logo silk-screen decorative plate.

19. The data center micro-module device according to claim 13, further comprising a display screen, an access controller, and an emergency stop button which are installed on the openable and closable door of the door case; and
the access controller and the emergency stop button are adjacent to the display screen.

20. The data center micro-module device according to claim 1, wherein the access door is a slidable glass door which is capable of sliding into or out of the door case in a translational manner.
